(19) United States
(12) Patent Application Publication
(10) Pub. No.: US 2012/0051012 A1
(43) Pub. Date: Mar. 1, 2012

(54) DISPLAY DEVICE WITH NOISE SHIELDING STRUCTURE

(75) Inventors: Sung Yong JOO, Yongin-si (KR); Won Myung WOO, Seoul (KR); Sung Bum JUNG, Yongin-si (KR)

(73) Assignee: SAMSUNG ELECTRONICS CO., LTD., Suwon-si (KR)

(21) Appl. No.: 13/170,863

(22) Filed: Jun. 28, 2011

(30) Foreign Application Priority Data
Aug. 30, 2010 (KR) 10-2010-0083885

(51) Int. Cl. H05K 5/00; H05K 7/00

(52) U.S. Cl. 361/753; 361/760; 361/782

(57) ABSTRACT

A display device including a front cover and a rear cover coupled to each other in order to receive a display panel, drive board and power supply board, is provided. A shield case mounted on the power supply board and coupled to the rear cover removes noise conducted to the rear cover. The shield case serves to disperse and absorb noise conducted to the rear cover, enabling removal of the noise. A frame ground terminal of a socket is connected to the shield case in order to allow the shield case to be used as a ground, resulting in an increased ground area. Further, the shield case may reduce radiation noise and conduction noise generated during driving of a plurality of drive units provided in the display device.

### CROSS-REFERENCE TO RELATED APPLICATION

This application claims the benefit of Korean Patent Application No. 2010-0083885, filed on Aug. 30, 2010 in the Korean Intellectual Property Office, the disclosure of which is incorporated herein by reference.

### BACKGROUND

1. Field

The exemplary embodiments relate to a display device for improving a noise shielding structure of a circuit board.

2. Description of the Related Art

Generally, display devices serve to visually display stereoscopic images. In recent years, flat panel display devices, which are lighter and smaller than cathode ray tubes, have been developed.

Representative examples of flat panel display devices include a Liquid Crystal Display (LCD), an Electro-Luminescence Display (ELD), a Field Emission Display (FED), and a Plasma Display Panel (PDP).

These flat panel display devices may require high power in order to provide for smooth operation thereof, and thus, are relatively sensitive to changes in frequency of input power.

In the case of a plasma display panel, a plurality of small cells is arranged between two thin glass panels. Positive and negative electrodes are provided above and below the cells in order to cause a discharge of plasma (neon and argon) therebetween. Since ultraviolet light generated by a plasma discharge is converted into visible light in order to form a color image, a higher power than the power necessary for a liquid crystal display may be necessary. Consequently, the plasma display panel is relatively sensitive to changes in the frequency of input power, which can cause severe noise.

In addition, the plasma display panel may frequently cause Electro Magnetic Interference (EMI) due to a sudden voltage change resulting from a drive signal, which drives the plurality of cells, being repeatedly switched on or off and voltages between On-time and Off-time having a difference of several tens to hundreds of volts, or more.

EMI may have a negative effect on a user and may deteriorate normal operation of respective constituent elements of a Printed Circuit Board (PCB) provided in the plasma display panel.

For this reason, the plasma display panel may require a high-output Switching Mode Power Supply (SMPS) for smooth operation thereof. In this situation, the larger the plasma display panel, the more necessary is it to increase the output of a SMPS. In addition, a noise filter may be necessary in order to remove noise caused by a change in the frequency of input power, when the SMPS outputs high power.

If the SMPS is changed on a per size basis of the plasma display panel, it may be necessary to design the noise filter (i.e. an inlet of an Alternating Current (AC) socket) in consideration of EMI.

Moreover, the larger the plasma display panel, the more AC cable may be required to connect the noise filter and the SMPS to each other, resulting in an increase in price.

### SUMMARY

Therefore, it is one aspect of the exemplary embodiments to provide a display device in which a socket and a line filter are mounted on a Switching Mode Power Supply (SMPS) of a power supply board.

It is another aspect of the exemplary embodiments to provide a display device in which a shield case is mounted on a power supply board while being partially coupled to a rear cover.

It is a further aspect of the exemplary embodiments to provide a display device in which a socket and a line filter are first mounted to an SMPS of a power supply board and thereafter, a shield case is mounted to the power supply board, in order to receive the socket and the line filter therein.

Additional aspects of the exemplary embodiments will be set forth, in part, in the description which follows and, in part, will be obvious from the description, or may be learned by practice of the exemplary embodiments.

In accordance with one aspect of the exemplary embodiments, a display device includes a front cover, a display panel disposed inside the front cover in order to display an image, a drive board which outputs a drive signal so as to display the image on the display panel, a power supply board which supplies drive power to the drive board, a rear cover coupled to the front cover in order to receive the display panel, drive board and power supply board, and a shield case mounted on the power supply board and coupled to the rear cover in order to remove noise conducted to the rear cover.

The shield case may disperse and absorb noise conducted to the rear cover during driving of the drive board.

The shield case may include a lead which is coupled to the power supply board.

The shield case may include a coupling portion which is coupled to the rear cover.

The rear cover may include a fastening portion located in a manner which corresponds to the coupling portion of the shield case, in order to be coupled to the coupling portion.

The display device may further include an inlet including a socket having two power terminals and a frame ground terminal. The inlet is connected to an external power source via the respective terminals, and the inlet may include a line filter which removes power noise from the external power source; and the shield case may receive the inlet.

The shield case may be connected to the frame ground terminal of the socket.

The shield case may include a socket opening which is located in a manner which corresponds to the socket.

The rear cover may include a plug inserting portion located in a manner which corresponds to the socket opening which exposes the socket, into which a plug to be connected to the socket is inserted.

The shield case may have a hole in order to emit heat generated from the inlet.

The shield case may receive a socket connected to an external power source, and the socket may be connected to the power supply board.

In accordance with another aspect of the exemplary embodiments, a display device includes a display panel, a drive board which outputs an image display drive signal to the display panel, a power supply board which supplies drive power to the drive board, and an inlet mounted to the power supply board and including a socket connected to an external power source and a line filter in order to remove noise from power of the external power source and to supply power to the power supply board.

The inlet may be connected, via cables, to a printed circuit pattern of the power supply board.

The line filter may include first and second normal mode choke coils respectively connected to two power terminals of the socket, a line cross capacitor connected between the first and second normal mode choke coils, and first and second common mode choke coils respectively connected to both ends of the line cross capacitor.

The first and second normal mode choke coils may remove normal mode noise of the power supplied from the socket, in combination with the line cross capacitor.

The first and second common mode choke coils may remove low-band common mode noise from the power supplied from the socket.

The line filter may further include a line bypass capacitor connected between a frame ground terminal of the socket and the second common mode choke coil. The line bypass capacitor may remove both high-band common mode noise and normal mode noise from the power supplied from the socket.

The display device may further include a shield case which receives the inlet.

The inlet and the shield case may be spaced apart from each other by a predetermined distance.

The first and second normal mode choke coils, line cross capacitor and first and second common mode choke coils may be connected, via leads, to one another.

### BRIEF DESCRIPTION OF THE DRAWINGS

These and/or other aspects of the exemplary embodiments will become apparent and more readily appreciated from the following description, taken in conjunction with the accompanying drawings of which:

FIG. 1 is an exploded perspective view of a display device according to an exemplary embodiment;

FIG. 2 is a view illustrating a detailed configuration of a drive board provided in the display device according to an exemplary embodiment;

FIG. 3 is a view illustrating a noise generation path in a rear cover provided in the display device according to an exemplary embodiment;

FIG. 4 is a view illustrating a configuration of a cover, shield case, and line filter provided in the display device according to an exemplary embodiment;

FIG. 5 is a circuit diagram of a line filter provided in the display device according to an exemplary embodiment;

FIG. 6 is a perspective view of the shield case provided in the display device according to an exemplary embodiment;

FIGS. 7A and 7B are graphs illustrating radiation noise before and after mounting the shield case onto the display device according to an exemplary embodiment; and

FIGS. 8A and 8B are graphs illustrating conduction noise before and after mounting the shield case onto the display device according to an exemplary embodiment.

### DETAILED DESCRIPTION

Reference will now be made in detail to the exemplary embodiments, examples of which are illustrated in the accompanying drawings, wherein like reference numerals refer to like elements throughout.

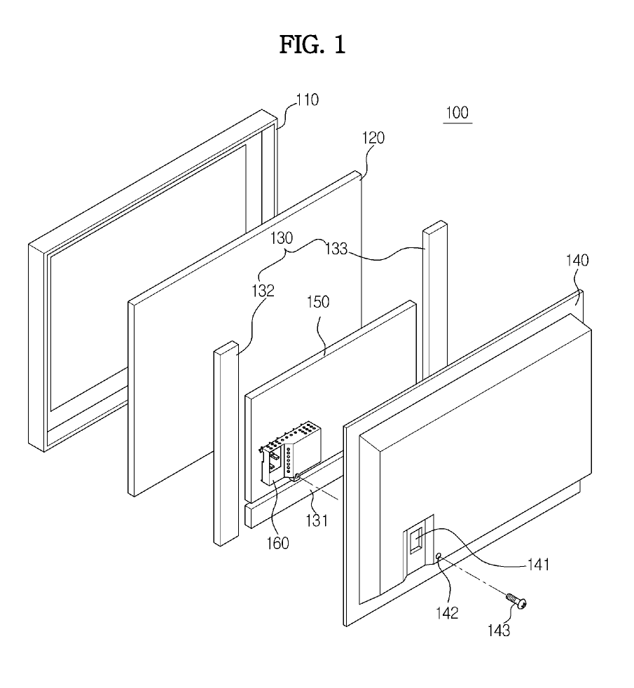

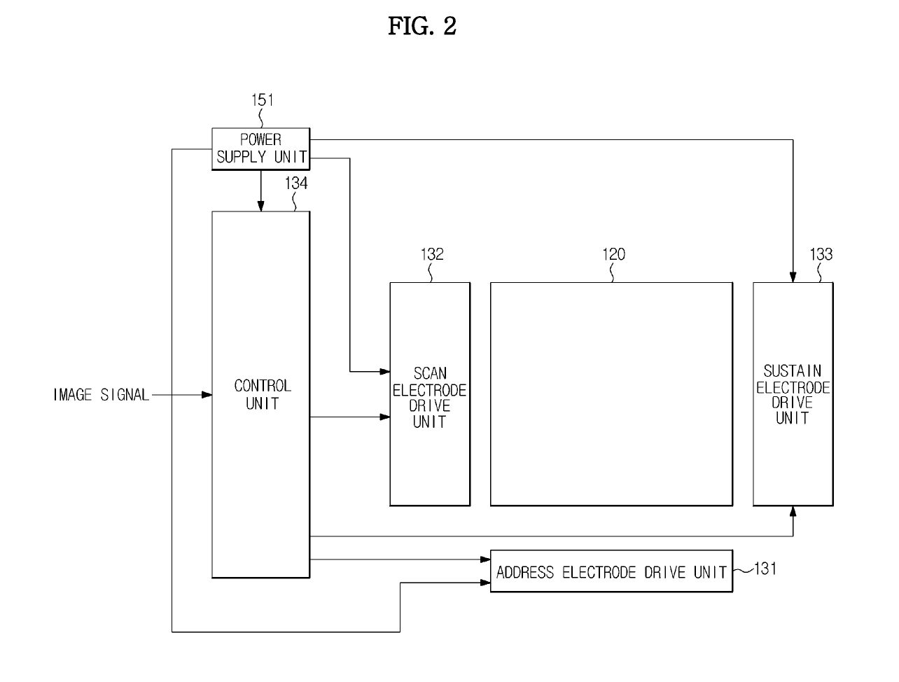

FIG. 1 is an exploded perspective view of a display device according to an exemplary embodiment. The display device will be described hereinafter with reference to FIGS. 2 to 6.

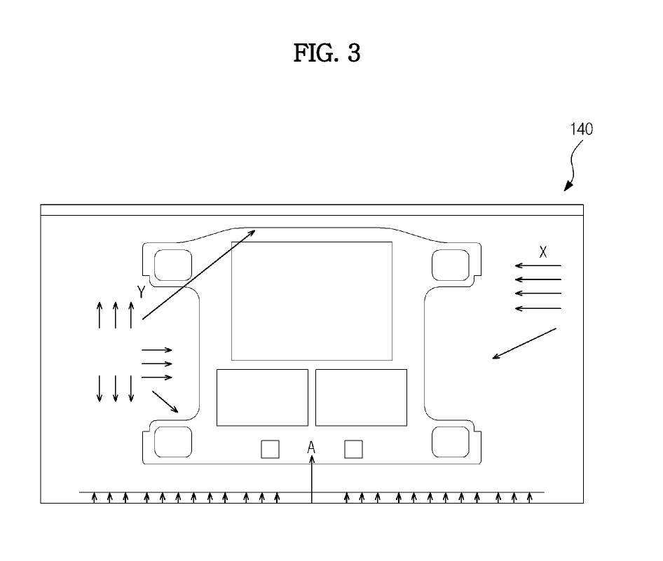

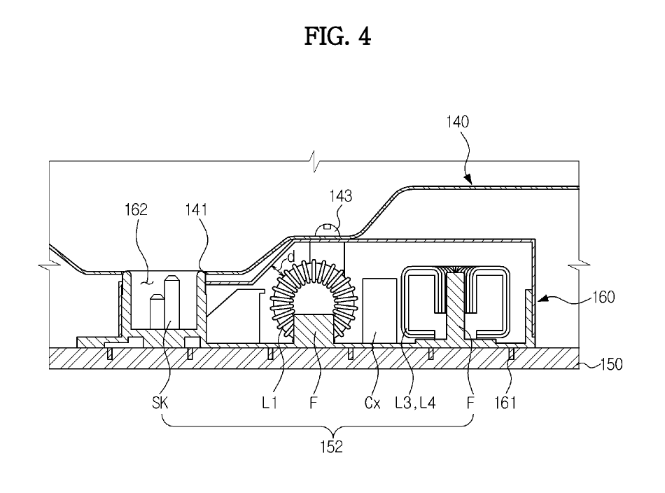

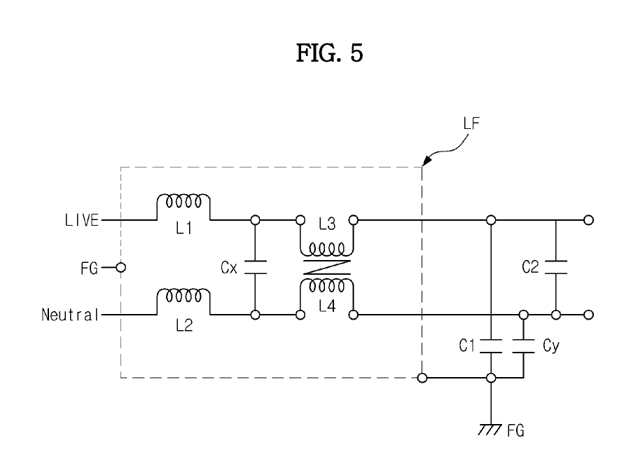

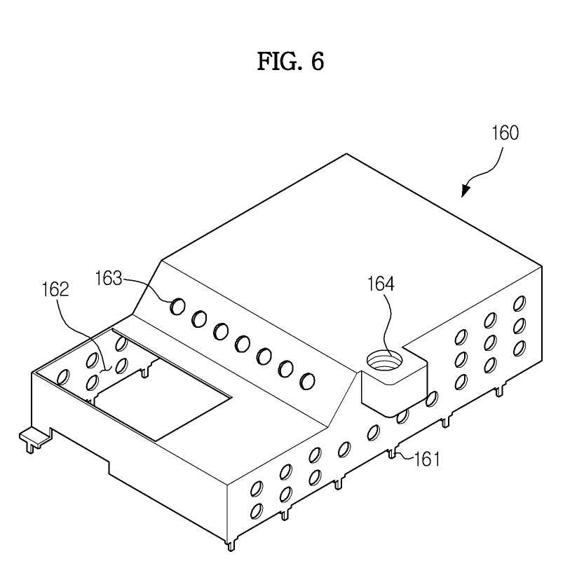

FIG. 2 is a view illustrating a detailed configuration of a drive board provided in the display device. FIG. 3 is a view illustrating a noise generation path of a rear cover provided in the display device, FIG. 4 is a view illustrating a configuration of a cover, shield case, and line filter provided in the display device according to an exemplary embodiment. FIG. 5 is a circuit diagram of a line filter provided in the display device. FIG. 6 is a perspective view of the shield case provided in the display device.

A Plasma Display Panel (PDP) will serve as an exemplary form of the display device and hereinafter, will be referred to as a plasma display device.

Plasma display device 100 includes a front cover 110, a display panel 120, a drive board 130, a rear cover 140, a power supply board 150, and a shield case 160.

Front cover 110 of plasma display device 100 is provided at a front surface of display panel 120 and serves to protect display panel 120 from external shock. Front cover 110 includes a glass and a front filter.

The front filter includes an optical film, an Electro Magnetic Interference (EMI) shield film, an infrared shield film, etc.

The glass serves to prevent the front filter from being damaged by external shock. The optical film serves to lower brightness of red R and green G light transmitted from display panel 120, while raising the brightness level of blue B light. The EMI shield film serves to block electromagnetic waves transmitted from display panel 120, in order to prevent emission of the electromagnetic waves.

The infrared shield film serves to shield infrared light emitted from display panel 120 and prevent excessive emission of infrared light, beyond a reference value, in order to assure normal transmission of signals using infrared light, e.g., from a remote controller.

Display panel 120 is connected to a plurality of address electrodes (not shown), scan electrodes (not shown) and sustain electrodes (not shown). Here, the plurality of address electrodes, scan electrodes and sustain electrodes are driven upon receiving drive signals from drive board 130.

Display panel 120 is adapted to display an image by generating visible light via discharge when current is applied between the scan electrodes and the address electrodes.

More specifically, display panel 120 includes a plurality of address electrodes aligned in vertical rows, and a plurality of pairs of scan electrodes and sustain electrodes aligned in horizontal rows.

The plurality of sustain electrodes are provided in order to correspond to the respective scan electrodes and one end of each sustain electrode is connected to a common electrode. Display panel 120 consists of a substrate (not shown) on which the sustain electrodes and the scan electrodes are disposed, and a substrate (not shown) on which the address electrodes are disposed.

The two substrates are arranged to face each other with a discharge space interposed therebetween such that the scan electrodes and the sustain electrodes are perpendicular to the address electrodes. In this configuration, discharge spaces at intersections between the address electrodes and the sustain electrodes and the scan electrodes define discharge cells.

As illustrated in FIG. 2, drive board 130 includes an address electrode drive unit 131, a scan electrode drive unit 132, a sustain electrode drive unit 133, and a control unit 134.

Address electrode drive unit 131, scan electrode drive unit 132, sustain electrode drive unit 133 of drive board 130 are connected to the address electrodes, scan electrodes and sustain electrodes of the display panel 120 via a Flexible Printed Circuit (FPC) (not shown), and provide the plurality of address electrodes, scan electrodes and sustain electrodes of display panel 120 with drive signals, in response to an instruction from control unit 134.

More specifically, address electrode drive unit 131 receives an address electrode drive control signal from the control unit 134 and applies a display data signal to each address electrode to enable selection of the discharge cells.

Scan electrode drive unit 132 receives a scan electrode drive signal from the control unit 134 and applies a drive voltage to the scan electrodes.

Sustain electrode drive unit 133 receives a sustain electrode drive control signal from control unit 134 and applies a drive voltage to the sustain electrodes.

Control unit 134 receives an image signal from an external source and outputs the address electrode drive control signal, sustain electrode drive control signal and scan electrode drive control signal.

Control unit 134 divides a frame into a plurality of sub-fields in order to drive the sub-fields respectively. Each sub field consists of a reset period, an address period and a sustain period, on the basis of a time variable operation.

Rear cover 140 is coupled to front cover 110 such that display panel 120 and drive board 130 are received therebetween, thereby protecting display panel 120, drive board 130 and other interior components from external shock.

Rear cover 140 is provided with a plug inserting portion 141 and a fastening portion 142.

Plug inserting portion 141 is located in a manner so as to correspond to a socket opening 162 of shield case 160, in order to allow a terminal of a socket SK to be exposed to the outside through socket opening 162 of shield case 160.

Specifically, a plug (not shown) is inserted into plug inserting portion 141 of rear cover 140. In this situation, the inserted plug is connected to each terminal of the socket SK through socket opening 162 of shield case 160.

Fastening portion 142 is located in a manner so as to correspond to a coupling portion 164 of shield case 160. As a bolt 143 is fastened through fastening portion 142 of rear cover 140 and coupling portion 164 of the shield case 160, shield case 160 and rear cover 140 are mechanically and electrically connected to each other.

Rear cover 140 is made of a conductive metal and functions as an antenna. Specifically, when noise generated from the front filter of front cover 110, the plurality of drive units of drive board 130 and power supply board 150 are amplified and transmitted to rear cover 140, the rear cover 140 serves to dampen the noise.

In particular, severe radiation noise is transmitted to rear cover 140 during driving of address electrode drive unit 131, scan electrode drive unit 132 and sustain electrode drive unit 133. The transmission path of the noise is illustrated in FIG. 3.

The shield case 160, which is electrically and mechanically coupled to the rear cover 140, serves to increase a ground area, thereby serving to damp radiation noise of each drive unit generated during driving of the address electrode drive unit 131, scan electrode drive unit 132 and sustain electrode drive unit 133.

Power supply board 150 is disposed close to scan electrode drive unit 132 and address electrode drive unit 131, and is provided with a power supply unit 151. Power supply unit 151 serves to supply the power required for driving plasma display device 100 to the respective drive units 131, 132 and 133 and the control unit 134.

Power supply unit 151 of power supply board 150 is a Switching Mode Power Supply (SMPS).

Switching mode power supply unit 151 of plasma display device 100 sets up or boosts up input power of 90 to 270 Vrms, having passed through a line filter LF of an inlet 152 from an external power source, and outputs a Direct Current (DC) voltage of about 370 to 400 VDC. The output voltage is supplied to the various constituent elements which are required for driving plasma display device 100 by way of a plurality of DC/DC converters (not shown).

The DC/DC converters include a plurality of DC/DC converters for supplying high-voltage sustain electrode drive power and address electrode drive power, and a plurality of DC/DC converters for supplying low-voltage power.

The address electrode drive power is supplied to the address electrode drive unit 131, and the sustain electrode drive power is supplied to the sustain electrode drive unit 133, and simultaneously to scan electrode drive unit 132.

The power output from the plurality of DC/DC converters (not shown) of power supply unit 151 is input into respective drive units 131 to 134 of drive board 130 in order to drive plasma display device 100.

Power supply unit 151 employs Power Factor Correction (PFC) to improve a power factor. The PFC may utilize a boost topology having a superior power factor for improved performance.

Since very high surge current flows during discharge, based on the operating principle of a PDP, power supply unit 151 is configured such that a plurality of large capacitors (not shown) are added in parallel to the plurality of DC/DC converters, which supply sustain drive power and address drive power.

Power supply unit 151 of plasma display device 100 includes a switching device (not shown) to provide each of a plurality of electrodes with required power via high-speed switching.

As illustrated in FIG. 4, power supply board 150 is provided with inlet 152, which is connected to an external commercial AC power source to apply commercial power to power supply unit 151. Inlet 152 is located close to scan electrode drive unit 132 and address electrode drive unit 131.

Inlet 152 includes the socket SK, to which the plug (not shown) connected to the external commercial AC power source is connected, and the line filter LF to remove noise (EMI) of the external commercial AC power source.

The socket SK has two power terminals, designated by LIVE and Neutral, connected to the plug (not shown), and a single frame ground terminal FG. Each terminal LIVE, Neutral or FG is connected to the line filter LF.

The frame ground terminal FG of the socket SK may be connected to shield case 160. Thus, the wide area of shield case 160 may be used as a ground.

The socket SK is connected to the plug (not shown). In this case, the socket SK may receive 3-phase power from the external commercial AC power source and supplies the received power to the line filter LF via each terminal.

Here, the socket SK may provide a path for introducing external noise via a cable connected to each terminal, and a discharge path of internal noise from plasma display device 100.

Noise carried by the cable connected to each terminal of the socket SK is divided into normal mode noise and common mode noise. The normal mode noise is input via power cables connected to the power terminals LIVE and Neutral of the socket SK to reciprocate between the power cables. The common mode noise is transmitted between the power cables connected to the two power terminals LIVE and Neutral of the socket SK and a ground cable connected to the frame ground terminal FG.

To remove both the normal mode noise and the common mode noise generated in the cables connected to the respective terminals of the socket SK, the line filter LF is installed to the socket SK.

More particularly, line filter LF is directly connected to the socket SK. The line filter LF receives power of 90 to 270 Vrms from the external commercial AC power source and suppresses internal and external high-frequency noise, thereby suppressing conduction of noise from the external commercial AC power source to plasma display device 100.

Line filter LF may make the irregular frequencies of the commercial AC power input from the socket SK uniform, enabling a supply of stabilized power to be supplied to respective drive units 131 to 134.

As illustrated in FIGS. 4 and 5, line filter LF includes first and second normal mode choke coils L1 and L2, a line cross capacitor Cx, and first and second common mode choke coils L3 and L4.

First and second normal mode choke coils L1 and L2, line cross capacitor Cx, and first and second common mode choke coils L3 and L4 of line filter LF are mounted on power supply board 150 by respective supporting posts F, and are electrically connected to power supply unit 151 via cables.

First and second normal mode choke coils L1 and L2, line cross capacitor Cx, and first and second common mode choke coils L3 and L4 of line filter LF are electrically connected to one another using respective leads of power supply board 150, rather than using a printed circuit pattern.

Line filter LF includes first normal mode choke coil L1 connected to the cable of the power terminal LIVE of the socket SK, and second normal mode choke coil L2 connected to the cable of the power terminal Neutral of the socket SK.

Both ends of the line cross capacitor Cx, connected between the two normal mode choke coils L1 and L2, are connected and coupled to first and second common mode choke coils L3 and L4.

First and second common mode choke coils L3 and L4 are connected to a plurality of capacitors C1, C2 and Cy.

More specifically, a first capacitor C1 is connected between the first and second common mode choke coils L3 and L4. A second capacitor C2 is connected between the first common mode choke coil L3 and the frame ground terminal FG. A line bypass capacitor Cy is connected between second common mode choke coil L4 and frame ground terminal FG. Frame ground terminal FG is connected to shield case 160, and line bypass capacitor Cy is connected to the frame ground FG via the shortest course.

First and second normal mode choke coils L1 and L2 are wound on an iron powder core to create magnetic flux in a given direction. The iron powder core may effectively suppress normal mode noise in combination with the line cross capacitor Cx due to a high saturated magnetic flux density, low magnetic permeability and wide frequency bandwidth, thereof.

First and second common mode choke coils L3 and L4 are wound on a single ferrite core having high magnetic permeability and low hysterisis loss. Winding coils having the same inductance on the ferrite core in opposite directions may prevent the core from being magnetized by current supplied to power supply unit 151.

Specifically, as magnetic fluxes of currents flowing in opposite directions through the first and second common mode choke coils L3 and L4 offset each other, the first and second common mode choke coils L3 and L4 may act as inductors with respect to common mode noise, thereby removing low-band common mode noise.

Also, the first and second common mode choke coils L3 and L4 are coupled to the line bypass capacitor Cy, in order to more effectively remove common mode noise.

Specifically, capacitors C1, C2 and Cy bypass high-band noise to a ground, thereby removing common mode voltage caused by common mode noise.

In this manner, low-band normal mode noise may be removed by use of the line cross capacitor Cx, and low-band common mode noise may be removed by reducing alleviating magnetic fluxes of currents flowing through first and second common mode choke coils L3 and L4. Also, high-band common mode noise and normal mode noise may be removed using the capacitors C1, C2 and Cy connected to first and second common mode choke coils L3 and L4.

By using shield case 160 as a ground, line bypass capacitor Cy bypasses noise at a stable ground, and this may improve a self-resonance frequency of approximately 10 MHz.

Socket SK of inlet 152 is installed close to line filter LF. This may reduce a length of the cable connected to each terminal of the socket SK, thereby reducing conduction noise (i.e. normal mode noise and common mode noise) that is induced via the cable.

Line filter LF of inlet 152 and power supply unit 151 are connected to each other via a cable, rather than being connected via the printed circuit board of power supply board 150, resulting in increased utility of power supply board 150. That is, easy pattern design with respect to lightning parts of power supply board 150 at the position of inlet 152 or AC voltage detection may be possible.

In this situation, by reducing a length of the cable connecting the line filter LF of inlet 152 and power supply unit 151 to each other, it may be possible to reduce the amount of electromagnetic interference transmitted by the cable, i.e. conduction noise (normal mode noise and common mode noise).

As illustrated in FIG. 4, shield case 160 is mounted on power supply board 150 in order to receive inlet 152 therein and is coupled to rear cover 140 in order to disperse and absorb noise (EMI) conducted to the rear cover 140.

A configuration of shield case 160 will be described in detail with reference to FIG. 6.

Shield case 160 is spaced apart from line filter LF by a predetermined distance d so as not to be affected by magnetic flux of the line filter LF. Shield case 160 serves to block radiation noise generated by a parasitic component of line filter LF.

Shield case 160 is connected to frame ground terminal FG of the socket SK of inlet 152 and serves as a ground through which noise is bypassed and removed.

Shield case 160 includes leads 161, a socket opening 162, holes 163, and a coupling portion 164.

Plurality of leads 161 is coupled to power supply board 150. In this situation, plurality of leads 161 may be coupled to power supply board 150 via soldering.

In this way, shield case 160 is mounted to power supply board 150 using leads 161 rather than using a printed circuit board, resulting in an easy pattern design with respect to lightning parts of power supply board 150 at the position of inlet 152 or AC voltage detection.

Socket opening 162 is located to correspond to the socket SK of inlet 152 in order to expose the socket SK of inlet 152 for connection between socket SK and the plug (not shown).

Plurality of holes 163 serve to emit heat generated from line filter LF and the socket SK of inlet 152.

Coupling portion 164 is located in a manner to correspond to fastening portion 142 of the rear cover 140 and is coupled to fastening portion 142 of rear cover 140 by use of bolt 143.

That is, shield case 160 is coupled to rear cover 140 via the coupling portion 164.

In this way, shield case 160 surrounds socket SK of inlet 152, thereby preventing vibration of socket SK upon fastening of the plug. This prevents breakdown of socket SK.

When socket SK and the line filter LF are surrounded by and received in conductive shield case 160 so as to be shielded from external noise, it may be possible to prevent leakage of noise generated from the socket SK and line filter LF.

Sustain pulses may be generated at a constant time interval in order to maintain plasma discharge. If the sustain pulses are introduced into the drive board 130 via a noise path X, a screen may suffer from generation of sustain noise. In this situation, shield case 160 may act to disperse and absorb the sustain noise distributed and conducted to rear cover 140, thereby preventing the sustain noise from having an effect on drive board 130.

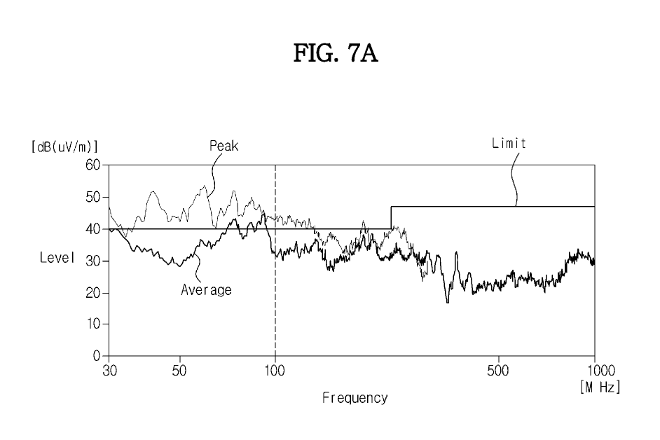

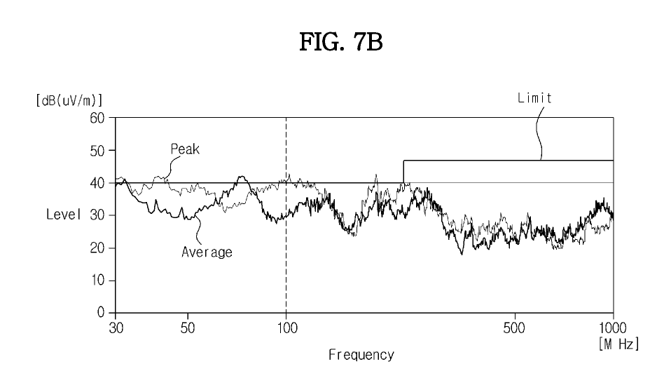

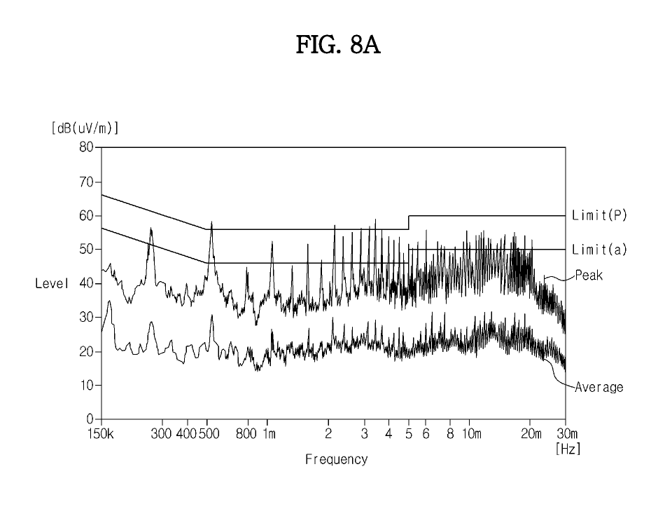

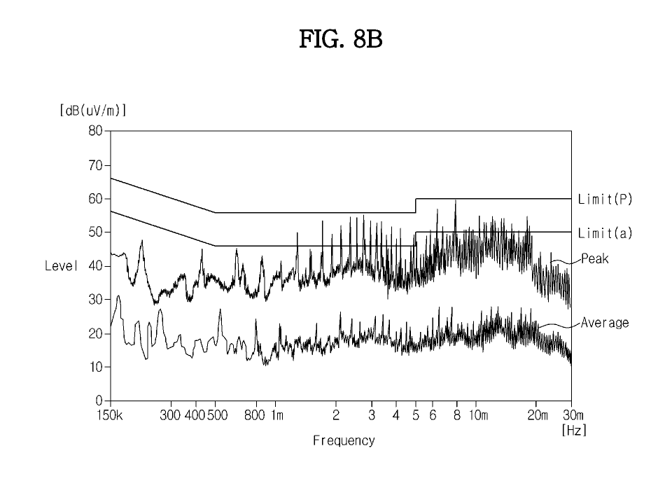

This will now be described in detail with reference to FIGS. 7A, 7B, 8A and 8B.

FIGS. 7A and 7B are graphs of radiation noise before and after the shield case is mounted in the plasma display device. FIGS. 8A and 8B are graphs of conduction noise before and after the shield case is mounted in the plasma display device.

FIG. 7A is a graph of radiation noise before shield case 160 is mounted in plasma display device 100. FIG. 7B is a graph of radiation noise after shield case 160 is mounted in plasma display device 100.

In FIG. 7A, to identify radiation noise before shield case 160 is mounted in display device 100, a peak voltage and an average voltage on a per frequency basis are measured. In FIG. 7B, to identify radiation noise after shield case 160 is mounted in display device 100, a peak voltage and an average voltage on a per frequency basis are measured. The magnitude of radiation noise is measured based on a voltage value, and is given as a value of dB (μV). Here, 0 dB is μV.

As illustrated in FIG. 7A, before shield case 160 is mounted in display device 100, the peak voltage of radiation noise is significantly greater than an international standard voltage limit at a frequency of 100 MHz or less.

It will be appreciated that the peak voltage of radiation noise is slightly greater than or similar to the international standard voltage limit in a frequency range of 100 MHz to 300 MHz, and the average voltage of radiation noise is slightly greater than or similar to the international standard voltage limit in a frequency range of 80 MHz to 300 MHz.

The international standard voltage limit is a radiation noise voltage depending on a frequency.

On the other hand, as illustrated in FIG. 7B, after shield case 160 is mounted in display apparatus 100, both the peak voltage and average voltage of radiation noise are similar to the international standard voltage Limit at a frequency of 300 MHz or less, and are less than the international limit voltage Limit at a frequency of 300 MHz or more.

FIG. 8A is a graph of conduction noise before shield case 160 is mounted in plasma display device 100. FIG. 8B is a graph of conduction noise after shield case 160 is mounted in plasma display device 100.

As illustrated in FIG. 8A, to identify conduction noise before shield case 160 is mounted in display device 100, a peak voltage and an average voltage on a per frequency basis are measured. As illustrated in FIG. 8B, to identify conduction noise after shield case 160 is mounted in display device 100, a peak voltage and an average voltage on a per frequency basis are measured.

As illustrated in FIG. 8A, before shield case 160 is mounted in display device 100, the average voltage of conduction noise is lower than an international standard voltage limit (a) throughout the entire frequency range. However, the peak voltage of conduction noise is similar to an international standard voltage limit (P) throughout the entire frequency range.

In particular, it will be appreciated that the peak voltage of conduction noise exceeds the international standard voltage limit (P) in a frequency range of 2 MHz to 5 MHz.

The international standard voltage limit (P) is given with respect to the peak voltage of conduction noise on a per frequency basis, and the international standard voltage limit (a) is given with respect to the average voltage of conduction noise on a per frequency basis.

On the other hand, as illustrated in FIG. 8B, after shield case 160 is mounted in display apparatus 100, the average voltage of conduction noise is lower than the international standard voltage limit (a) throughout the entire frequency range.

It will also be appreciated that the peak voltage of conduction noise is stable throughout the entire frequency range and is lower than the international standard voltage limit (P).

In particular, it will be appreciated that the peak voltage of conduction noise has a remarkable difference before and after shield case 160 is mounted in display device 100, at a frequency of 5 MHz or less.

In this situation, shield case 160, coupled to rear cover 140, may disperse and absorb radiation noise and conduction noise transmitted to rear cover 140.

As is apparent from the above description, a display device according to an aspect of the exemplary embodiments may include a shield case to disperse and absorb sustain noise transmitted to a rear cover, achieving noise reduction.

Further, as a result of connecting a frame ground terminal of a socket to the shield case, the shield case may serve as a ground. This results in an increased area of the ground, which provides a stable ground.

Furthermore, the shield case may reduce radiation noise and conduction noise generated during the driving of a plurality of drive units provided in the display device, which provides the respective drive units with increased driving accuracy.

According to another aspect of the exemplary embodiments, the shield case receiving the line filter therein may remove radiation noise generated by parasitic components of common mode choke coils, and normal mode choke coils of the line filter.

Further, by connecting a line bypass capacitor and the frame ground terminal of the socket to each other, it may be possible to bypass noise and consequently, to improve the self-resonance frequency.

Furthermore, when mounting the socket and the line filter to a Switching Mode Power Supply (SMPS) of a power supply board, a reduced length cable may be used, resulting in a reduction in manufacturing costs and noise transmitted via the cable.

According to a further aspect of the exemplary embodiments, it may be possible to enhance space utilization of the power supply board by connecting the shield case to the socket of an inlet, and also connecting respective constituent elements of the line filter to each other, using leads.

While this invention has been particularly shown and described with reference to exemplary embodiments thereof, it will be understood by those of ordinary skill in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description but by the appended claims, and all differences within the scope of the claims will be construed as being included in the present invention.

What is claimed is:

1. A display device comprising:
a front cover;
a display panel which displays an image disposed inside the front cover;
a drive board which outputs a drive signal in order to display the image on the display panel;
a power supply board which supplies drive power to the drive board;
a rear cover coupled to the front cover and receiving the display panel, drive board and power supply board; and
a shield case mounted on the power supply board and coupled to the rear cover in order to remove noise conducted to the rear cover.

2. The display device according to claim 1, wherein the shield case disperses and absorbs sustain noise conducted to the rear cover during driving of the drive board.

3. The display device according to claim 1, wherein the shield case includes a lead which is coupled to the power supply board.

4. The display device according to claim 1, wherein the shield case includes a coupling portion which is coupled to the rear cover.

5. The display device according to claim 4, wherein the rear cover includes a fastening portion which is located in a manner such that it corresponds to the coupling portion of the shield case, and is coupled to the coupling portion.

6. The display device according to claim 1, further comprising an inlet including a socket having two power terminals and a frame ground terminal, the inlet being connected to an external power source via the respective terminals, and a line filter which removes noise of power supplied from the external power source,
wherein the shield case receives the inlet.

7. The display device according to claim 6, wherein the shield case is connected to the frame ground terminal of the socket.

8. The display device according to claim 6, wherein the shield case includes a socket opening which is located in a manner which corresponds to the socket.

9. The display device according to claim 8, wherein the rear cover includes a plug inserting portion which is located in a manner which corresponds to the socket opening in order to expose the socket, into which a plug to be connected to the socket is inserted.

10. The display device according to claim 6, wherein the shield case has a hole which emits heat generated from the inlet.

11. The display device according to claim 1, wherein the shield case receives a socket connected to an external power source, and the socket is connected to the power supply board.

12. A display device comprising:
a display panel;
a drive board which outputs an image display drive signal to the display panel;
a power supply board which supplies drive power to the drive board; and
an inlet mounted to the power supply board, the inlet including a socket connected to an external power source and a line filter which removes noise from power of the external power source and which supplies the power to the power supply board.

13. The display device according to claim 12, wherein the inlet is connected to a printed circuit pattern of the power supply board via a cable.

14. The display device according to claim 12, wherein the line filter includes:
first and second normal mode choke coils connected respectively to two power terminals of the socket;
a line cross capacitor connected between the first and second normal mode choke coils; and
first and second common mode choke coils connected across both ends of the line cross capacitor.

15. The display device according to claim 14, wherein the first and second normal mode choke coils remove normal mode noise of the power supplied from the socket in combination with the line cross capacitor.

16. The display device according to claim 14, wherein the first and second common mode choke coils remove low-band common mode noise from the power supplied from the socket.

17. The display device according to claim 14, wherein the line filter further includes a line bypass capacitor connected between a frame ground terminal of the socket and the second common mode choke coil.

18. The display device according to claim 17, wherein the line bypass capacitor removes both high-band common mode noise and normal mode noise from the power supplied by the socket.

19. The display device according to claim 12, further comprising a shield case which receives the inlet.

20. The display device according to claim 19, wherein the inlet and the shield case are spaced apart from each other by a predetermined distance.

21. The display device according to claim 12, wherein the first and second normal mode choke coils, line cross capacitor and first and second common mode choke coils are connected to one another via leads.
